(19) United States
(12) Patent Application Publication
(10) Pub. No.: US 2024/0006190 A1
(43) Pub. Date: Jan. 4, 2024

(54) METHOD OF MANUFACTURING SEMICONDUCTOR DEVICE USING SUFFRAGE TREATMENT PROCESS

(71) Applicant: SAMSUNG ELECTRONICS CO., LTD, Suwon-si (KR)

(72) Inventors: Jin-Hong PARK, Suwon-si (KR); Hogeun AHN, Suwon-si (KR); BoReum LEE, Suwon-si (KR); Sunguk JANG, Suwon-si (KR); Jiwan KOO, Suwon-si (KR); Seunghwan SEO, Suwon-si (KR)

(73) Assignees: SAMSUNG ELECTRONICS CO., LTD, Suwon-si (KR); RESEARCH & BUSINESS FOUNDATION OF SUNGKYEUNGAM UNIVERSITY, Suwon-si (KR)

(21) Appl. No.: 18/117,864

(22) Filed: Mar. 6, 2023

(30) Foreign Application Priority Data
Jul. 4, 2022 (KR) 10-2022-0082109

(51) Int. Cl. H01L 21/467; H01L 29/66; H01L 21/441

(52) U.S. Cl. CPC H01L 21/467; H01L 29/66969; H01L 21/441

(57) ABSTRACT

A method of manufacturing a semiconductor device includes forming a channel layer on a substrate, forming a mask on the channel layer, surface-treating an exposed surface of the channel layer exposed from the mask, forming an electrode on the exposed surface of the channel layer, and removing the mask. The channel layer includes a two-dimensional material, and the surface-treating of the exposed surface of the channel layer includes surface-treating the exposed surface of the channel layer with HCl.

### CROSS-REFERENCE TO RELATED APPLICATIONS

This application claims priority to Korean Patent Application No. 10-2022-0082109, filed on Jul. 4, 2022, in the Korean Intellectual Property Office, the contents of which are incorporated by reference herein in its entirety.

### BACKGROUND

The present disclosure relates a method for manufacturing a semiconductor device, and more particularly, relates to a method of manufacturing a semiconductor device using a surface treatment process.

Two-dimensional (2D) materials have excellent electrical, mechanical, and optical characteristics, and thus are drawing a lot of attention as next-generation semiconductor materials to replace Si, which has physical limitations.

In a method of manufacturing an electronic device using a two-dimensional material, it is important that a contact resistance between a two-dimensional material and an electrode depends on a process manner of forming the electrode on the two-dimensional material.

The contact resistance between the two-dimensional material and the electrode affects performance of the device, and thus an issue of reducing the contact resistance between the two-dimensional material and the electrode is raised.

### SUMMARY

One or more example embodiment provide a method of manufacturing a semiconductor device in which contact resistance between a two-dimensional material and an electrode is lowered.

According to an aspect of an example embodiment, a method of manufacturing a semiconductor device includes: forming a channel layer on a substrate; forming a mask on the channel layer; surface-treating an exposed surface of the channel layer exposed from the mask; forming an electrode on the exposed surface; and removing the mask, wherein the channel layer includes a two-dimensional material, and wherein the surface-treating includes surface-treating the exposed surface with Hydrogen Chloride (HCl). According to an aspect of an example embodiment, a method of manufacturing a semiconductor device includes: forming a channel layer on a substrate; forming a mask on the channel layer; surface-treating an exposed surface of the channel layer exposed from the mask; forming an electrode on the exposed surface; and removing the mask, wherein the channel layer includes a two-dimensional material, and wherein the surface-treating includes surface-treating the exposed surface with one of HBr, HF, HI, and HNO₃.

According to an aspect of an example embodiment, a method of manufacturing a semiconductor device includes: forming a channel layer on a substrate; forming a mask on the channel layer; surface-treating an exposed surface of the channel layer exposed from the mask; forming an electrode on the exposed surface; and removing the mask, wherein the channel layer includes a two-dimensional material, and wherein the surface-treating includes surface-treating the exposed surface with HCl at a concentration of 5%.

### BRIEF DESCRIPTION OF THE DRAWINGS

The above and other aspects, features, and advantages of the present disclosure will be more clearly understood from the following description of example embodiments taken in conjunction with the accompanying drawings, in which:

FIG. 1 is a cross-sectional view of a semiconductor device according to some example embodiments;

FIG. 2 is a flowchart of a method of manufacturing a semiconductor device according to some example embodiments;

FIGS. 3A, 3B, and 3C are cross-sectional views illustrating a method of manufacturing a semiconductor device shown in FIG. 2 according to an example embodiment;

FIGS. 4A and 4B are cross-sectional views illustrating a semiconductor device according to some example embodiments;

FIG. 5 is a cross-sectional view illustrating a semiconductor device according to some example embodiments;

FIGS. 6A, 6B, and 6C are diagrams for explaining electrical characteristics of a semiconductor device according to some example embodiments;

FIGS. 7A and 7B are diagrams for explaining electrical characteristics of a semiconductor device according to some example embodiments; and

FIG. 8 is a flowchart of a method of manufacturing a semiconductor device according to some example embodiments.

### DETAILED DESCRIPTION

Hereinafter, a method of manufacturing a semiconductor device according to example embodiments will be described in detail with reference to the drawings.

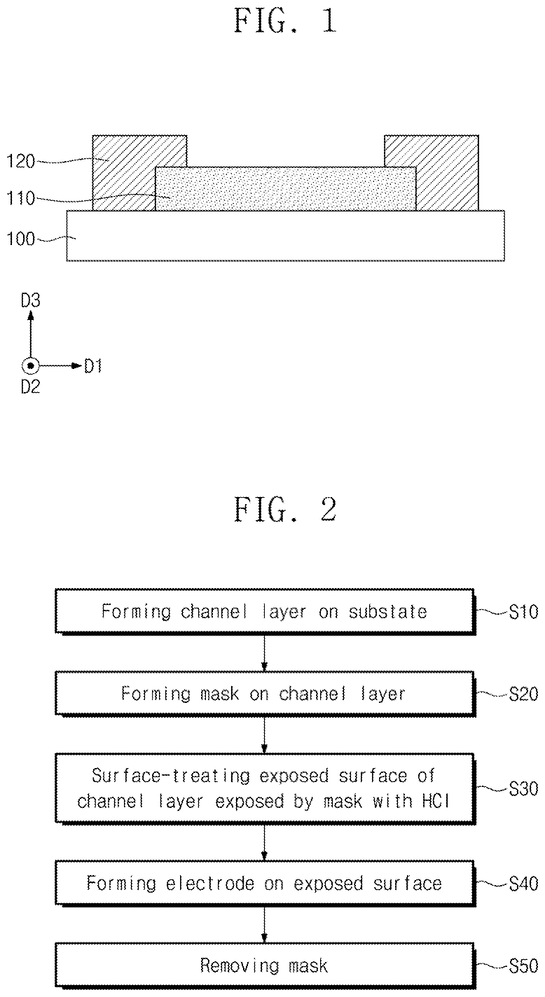

FIG. 1 is a cross-sectional view of a semiconductor device according to some example embodiments.

Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

Referring to FIG. 1, a semiconductor device according to an example embodiment may include a substrate 100, a channel layer 110 on the substrate, and an electrode 120.

The substrate 100 may be a Si, Ge, or glass substrate including an insulating layer. The insulating layer may include SiO₂, Al₂O₃, HfO₂, h-BN, or an organic insulating material.

The substrate 100 may have a plate shape extending along a plane extending in a first direction D1 and a second direction D2. The first direction D1 and the second direction D2 may cross each other. For example, the first direction D1 and the second direction D2 may be horizontal directions orthogonal to each other.

The channel layer 110 may be disposed on the substrate. The channel layer 110 may have a thickness of 10 nm to 900 μm. A width of the channel layer 110 may be smaller than a width of the substrate 100.

The channel layer 110 may include a two-dimensional material. The two-dimensional material may include one of a transition metal dichalcogenide (TMD) such as MoS₂, WS₂, MoSe₂, ReS₂, or WSe₂, graphene, silicene (a material in which Si atoms are bonded in two dimensions), or germanein (a material in which Ge atoms are bonded in two dimensions).

The electrode 120 may be disposed on the substrate 100. The electrode 120 may be in contact with a portion of the substrate 100. The electrode 120 may cover a portion of an upper surface of the channel layer 110. Each of a plurality of electrodes 120 may be in contact with a side surface of the channel layer 110. The electrode 120 may include at least one of Cr, Pd, Au, or graphene.

In an example embodiment, when the two-dimensional material of the channel layer 110 includes WSe₂ and the electrode 120 includes Cr, the channel layer 110 may operate as an N-type channel.

In an example embodiment, when the two-dimensional material of the channel layer 110 includes WSe₂ and the electrode 120 includes Pd, the channel layer 110 may operate as a P-type channel.

The semiconductor device including the substrate 100, the channel layer 110, and the electrode 120 may operate as a transistor. The electrode 120 may operate as a source electrode or a drain electrode. A gate may be disposed on the channel layer 110, the substrate 100 may include a gate, and the gate may be disposed on the channel layer 110 while the substrate 100 may include a gate.

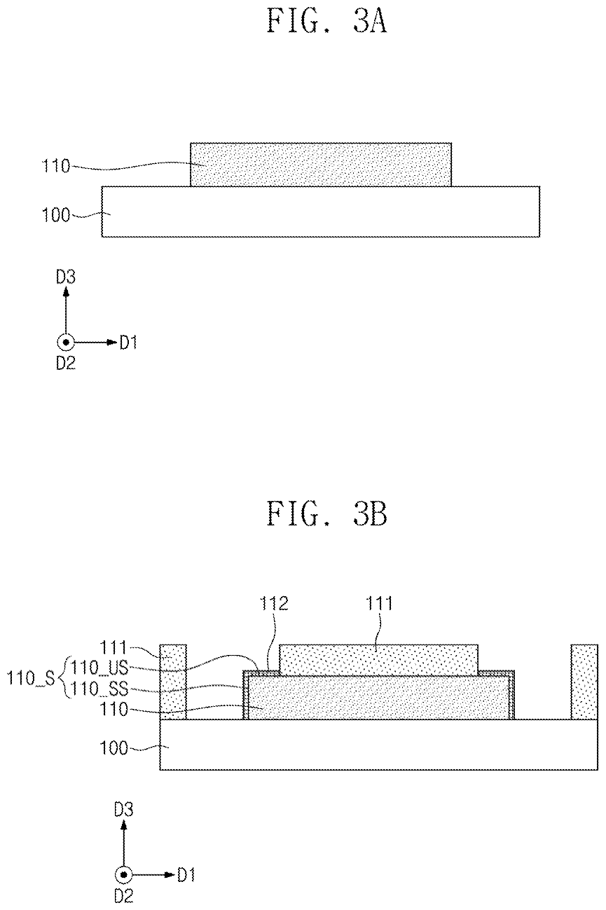

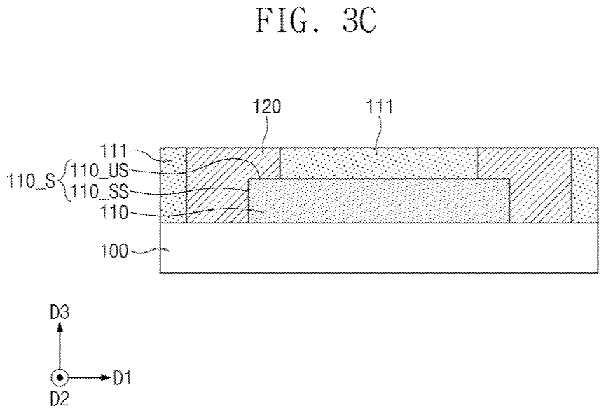

FIG. 2 is a flowchart of a method of manufacturing a semiconductor device according to some example embodiments. FIGS. 3A, 3B, and 3C are cross-sectional views illustrating a method of manufacturing a semiconductor device according to FIG. 2 consistent with an example embodiment.

Referring to FIGS. 2 and 3A, a channel layer 110 may be formed on a substrate 100 in S10. The channel layer 110 including a two-dimensional material may include, for example, TMD. In this case, the channel layer 110 may be formed by transferring onto the substrate 100 or may be formed by a chemical reaction of a metal precursor gas and H₂S gas. The channel layer 110 including a two-dimensional material may include, for example, graphene. In this case, the channel layer 110 may be formed by transferring the graphene onto the substrate 100, or may be formed by chemical vapor deposition (CVD).

Referring to FIGS. 2 and 3B, a mask 111 may be formed on the channel layer 110 in S20. The mask 111 may also be formed on the substrate 100. The mask 111 may cover a portion of the channel layer 110. The mask 111 may cover a portion of the substrate 100.

In an example embodiment, forming the mask 111 may include performing a photolithography process, or performing an electron beam (e-beam) lithography process. In an example embodiment, the mask 111 may include photoresist or polymethl methacrylate (PMMA).

After the mask 111 is formed, an exposed surface 110_S of the channel layer 110 exposed by the mask 111 may be surface-treated in S30. The exposed surface 110_S of the channel layer 110 exposed by the mask 111 may be a surface of the channel layer 110 on which the mask 111 is not formed. The surface-treating of the exposed surface 110_S may include surface-treating the exposed surface 110_S with hydrogen chloride (HCl). The exposed surface 110_S may include an upper exposed surface 110_US and a side exposed surface 110_SS. The side exposed surface 110_SS may extend in a third direction D3. The third direction D3 may intersect the first direction D1 and the second direction D2. For example, the third direction D3 may be a vertical direction perpendicular to the first direction D1 and the second direction D2. In an example embodiment, the upper exposed surface 110_US and the side exposed surface 110_SS may be orthogonal.

The surface-treating of the exposed surface 110_S of the channel layer 110 with HCl may include surface-treating the upper exposed surface 110_US and the side exposed surface 110_SS with HCl in a liquid, gaseous, or plasma state. The upper exposed surface 110_US and the side exposed surface 110_SS may be covered with a HCl layer 112 by surface treatment. Impurities on the upper exposed surface 110_US and the side exposed surface 110_SS may be removed by the surface treatment. Oxide groups on the upper exposed surface 110_US and the side exposed surface 110_SS may be removed by the surface treatment.

In an example embodiment, the surface-treating of the exposed surface 110_S may include surface-treating of the upper exposed surface 110_US and the side exposed surface 110_SS with HCl in a liquid state. In this case, a concentration of HCl may be 1% or more and 10% or less.

Referring to FIGS. 2 and 3C, an electrode 120 may be formed on the exposed surface 110_S after the surface treatment in S40. The electrode 120 may be formed by depositing or transferring a metal such as Cr, Pd, Au, or graphene, which is widely used in a semiconductor process, on the surface exposed by the mask 111.

The electrode 120 may be formed to be in contact with the upper exposed surface 110_US and the side exposed surface 110_SS of the channel layer 110.

The semiconductor device of FIG. 1 including the electrode 120, the channel layer 110, and the substrate 100 may be obtained by removing the mask 111.

The electrode 120 may be formed after the above-described surface treatment, and thus contact resistance between the electrode 120 and the channel layer 110 may be reduced compared to when the electrode is formed without the surface treatment.

The electrode 120 may be formed after the above-described surface treatment, and thus the impurities between the electrode 120 and the channel layer 110 may be reduced compared to when the surface treatment is not performed. Therefore, a Fermi level pinning phenomenon, a phenomenon in which a Schottky barrier occurs due to the impurities on a junction surface between the electrode 120 and the channel layer 110 regardless of a work function of the electrode 120, may be alleviated.

The impurities between the electrode 120 and the channel layer 110 may be reduced compared to when the surface treatment is not performed, and thus the exposed surface 110_S between the electrode 120 and the channel layer 110 may be relatively smooth. That is, surface roughness of the exposed surface 110_S between the electrode 120 and the channel layer 110 may be relatively small. Accordingly, an air-gap between the electrode 120 and the channel layer 110 may be reduced.

In an example embodiment, the surface-treating of the exposed surface 110_S may include surface-treating the exposed surface 110_S with a material including HBr, HF, HI, or another group 17 element. In this case, the material including HBr, HF, HI or another group 17 element, may be in a gaseous, liquid or plasma state. In an example embodiment, the surface-treating of the exposed surface 110_S may include surface-treating the exposed surface 110_S with a material including HNO₃.

The semiconductor device of FIG. 1 manufactured through the manufacturing method of FIG. 2 may be used for various purposes, such as a transistor, a diode, and an optical device, through a post process.

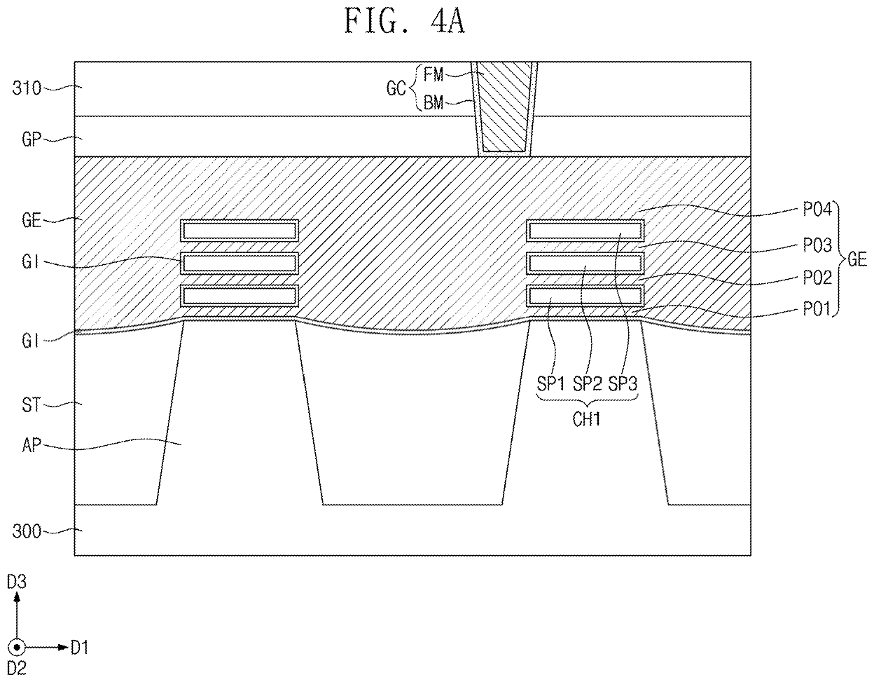

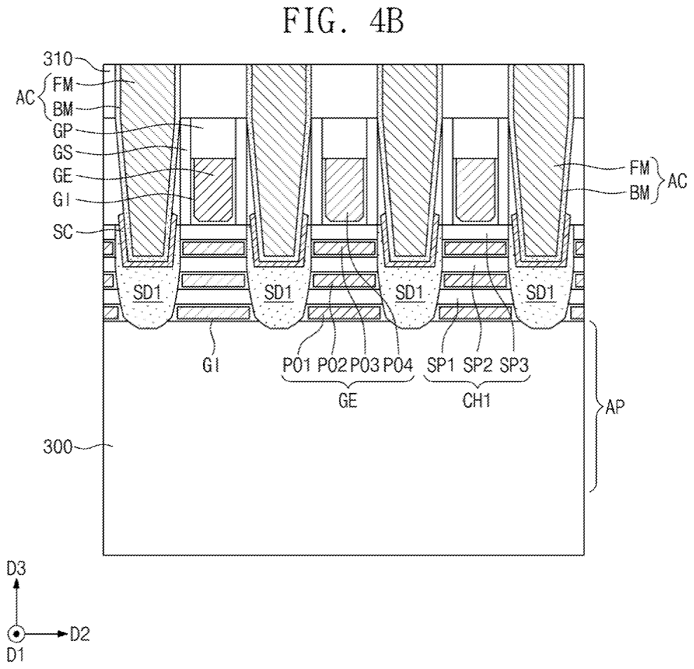

FIGS. 4A and 4B are cross-sectional views illustrating a semiconductor device according to some example embodiments.

FIGS. 4A and 4B show an Multi-Bridge-Channel Field Effect Transistor (MBCFET) structure to which the surface treatment according to FIG. 2 is applied.

Referring to FIGS. 4A and 4B, a substrate 300 may include an active pattern AP. The active pattern AP is a part of the substrate 300 and may comprise vertically protruding portions. A device isolation layer ST may be provided on the substrate 300. The device isolation layer ST may include a silicon oxide layer. The device isolation layer ST may not cover a channel pattern CH1 to be described later. A gate insulating layer GI may be provided on the active pattern AP and the device isolation layer ST.

A gate electrode GE may be provided on the active pattern AP. The channel pattern CH1 may be provided on the active pattern AP. The gate electrode GE may surround the channel pattern CH1. The channel pattern CH1 may include a first semiconductor pattern SP1, a second semiconductor pattern SP2, and a third semiconductor pattern SP3 that are sequentially stacked.

The gate electrode GE may include a first portion PO1 interposed between the active pattern API and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

A gate capping pattern GP may be provided on the gate electrode GE. An interlayer insulating layer 310 may be provided on the gate capping pattern GP. A gate contact GC electrically connected to the gate electrodes GE may be provided through the interlayer insulating layer 310 and the gate capping pattern GP.

The gate contact GC may include a conductive pattern FM and a barrier pattern BM surrounding the conductive pattern FM.

A plurality of source/drain patterns SD1 may be provided on the active pattern AP. Active contacts AC may be provided through the interlayer insulating layer 310 to be electrically connected to the source/drain patterns SD1, respectively. The active contact AC may include a conductive pattern FM and a barrier pattern BM surrounding the conductive pattern FM.

A pair of gate spacers GS may be respectively disposed on both sidewalls of the fourth portion PO4 of the gate electrode GE. The gate spacers GS may extend in a first direction D1 along the gate electrode GE. Upper surfaces of the gate spacers GS may be higher than upper surfaces of the gate electrode GE, respectively. The upper surfaces of the gate spacers GS may be coplanar with a lower surface of the interlayer insulating layer 310.

A metal-semiconductor compound layer SC, for example, a silicide layer, may be interposed between the active contact AC and the source/drain pattern SD1, respectively. The active contact AC may be electrically connected to the source/drain pattern SD1 through the metal-semiconductor compound layer SC. For example, the metal-semiconductor compound layer SC may include at least one of titanium-silicide, tantalum-silicide, tungsten-silicide, nickel-silicide, and cobalt-silicide.

In an example embodiment, after the channel pattern CH1 is formed, the surface of the channel pattern CH1 may be treated with HCl before the gate electrode GE is formed. Contact resistance may be reduced through surface treatment of HCl.

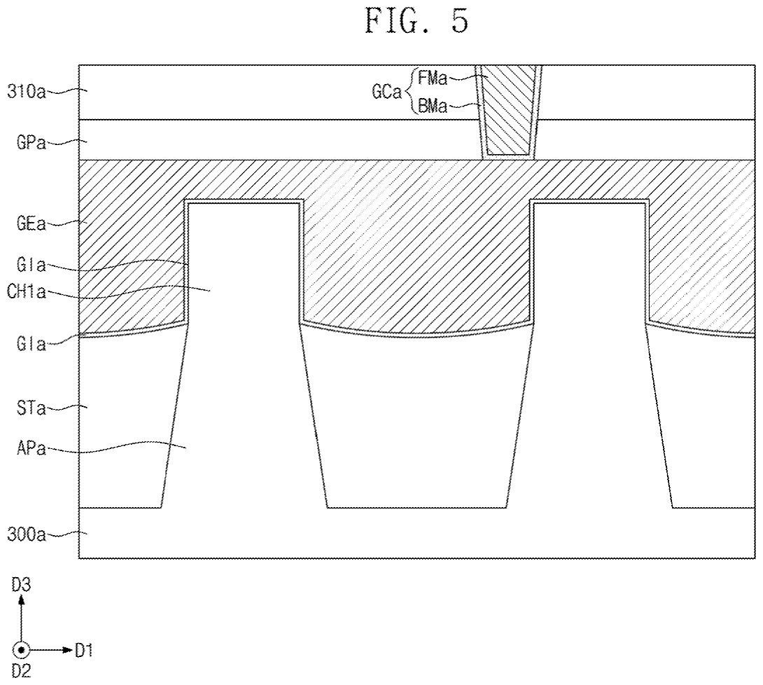

FIG. 5 is a cross-sectional view illustrating a semiconductor device according to some example embodiments.

FIG. 5 illustrates a fin field-effect transistor (FINFET) structure to which the surface treatment according to FIG. 2 has been applied, according to an example embodiment.

Similar to FIG. 4A, a substrate 300a may include an active pattern APa. A device isolation layer STa may be provided on the substrate 300a. A channel pattern CH1a may be provided on the active pattern APa. A gate insulating layer GI may be provided on the channel pattern APa and the device isolation layer STa.

A gate electrode GEa may be provided on a gate insulating layer GIa. A gate capping pattern GPa may be provided on the gate electrode GEa. An interlayer insulating layer 310a may be provided on the gate capping pattern GPa. A gate contact GCa may be provided through the interlayer insulating layer 310a and the gate capping pattern GPa and may be electrically connected to the gate electrodes GEa.

The gate contact GCa may include a conductive pattern FMa and a barrier pattern BMa surrounding the conductive pattern FMa.

In an example embodiment, after the channel pattern CH1a is formed, a surface of the channel pattern CH1a may be treated with HCl before the gate electrode GEa is formed. Contact resistance may be reduced through surface treatment of HCl.

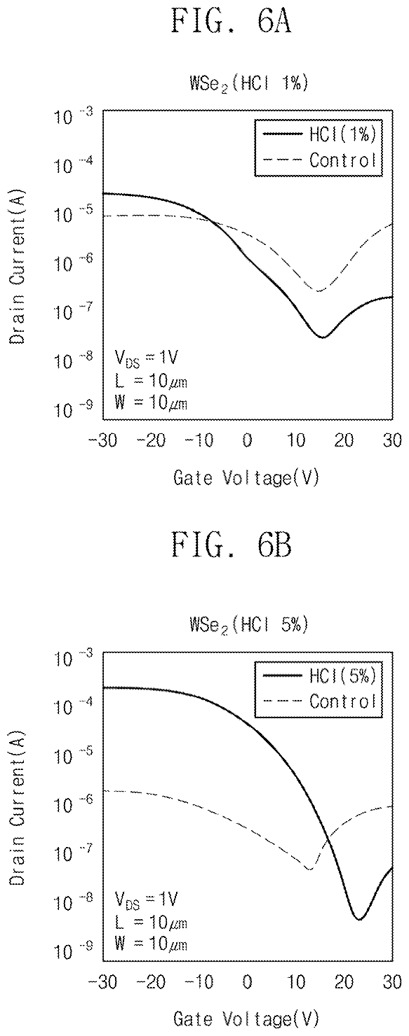

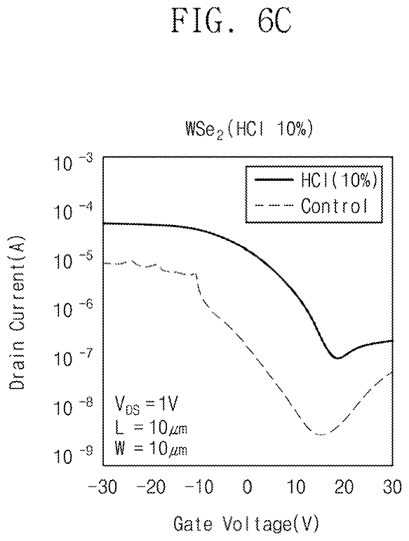

FIGS. 6A, 6B, and 6C are diagrams for explaining electrical characteristics of semiconductor devices according to some example embodiments.

FIGS. 6A, 6B, and 6C illustrate characteristics of transistors including channel layers 110 with WSe₂ which are surface-treated at a concentration of 1% of HCl (see FIG. 6A), 5% of HCl (see FIG. 6B), and 10% of HCl (see FIG. 6C), respectively. A result without HCl surface treatment is shown as a control.

In terms of an on-off ratio, which is a difference between a maximum value (Ion) and a minimum value (Ioff) of a drain current according to a gate voltage, it may be seen that a difference of the on-off ratio between the 1% condition (FIG. 6A) and the case without surface treatment (shown as Control) is relatively small due to the low concentration, and a different of the on-off ratio between the 5% condition (FIG. 6B) and the case without surface treatment (shown as Control) is relatively large. It may be seen that the maximum and minimum values of the drain current increase in the 10% condition (FIG. 6C) compared to the case without surface treatment (shown as Control) and thus the on-off ratio is relatively small due to a doping effect of high concentration of HCl.

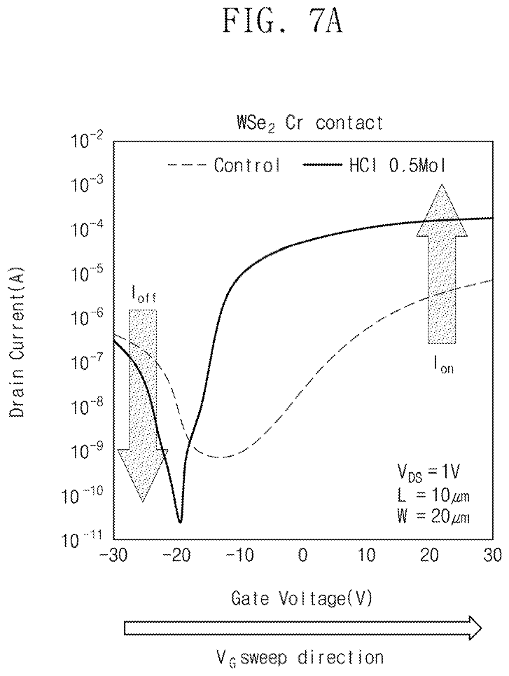

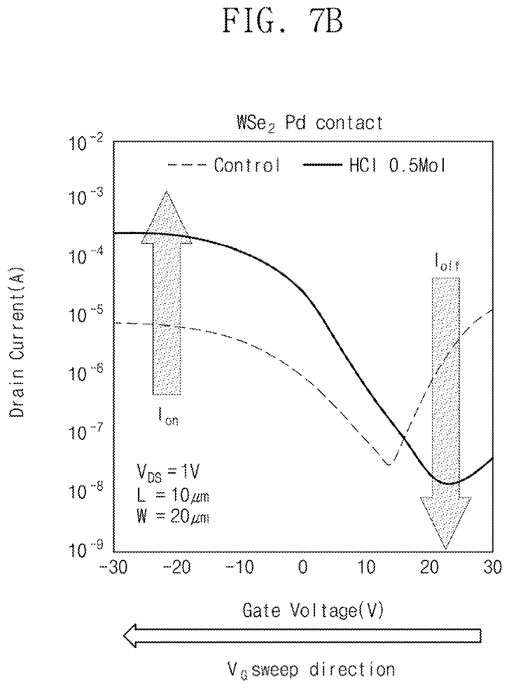

FIGS. 7A and 7B are diagrams for explaining electrical characteristics of a semiconductor device according to some example embodiments.

FIG. 7A illustrates characteristics of a transistor including a channel layer 110 with WSe₂ and an electrode 120 with Cr. In this case, it may be seen that the transistor operates as an N-channel transistor. It may be seen that an on-off ratio is increased when a surface of the channel layer 110 is treated with HCl 0.5 Mol concentration, compared to the case where the surface is not treated (shown as Control).

FIG. 7B illustrates characteristics of a transistor including a channel layer 110 with WSe₂ and an electrode 120 with Pd. In this case, it may be seen that the transistor operates as a P-channel transistor. It may be seen that an on-off ratio is increased when a surface of the channel layer 110 is treated with HCl 0.5 Mol concentration, compared to the case where the surface is not treated (shown as Control).

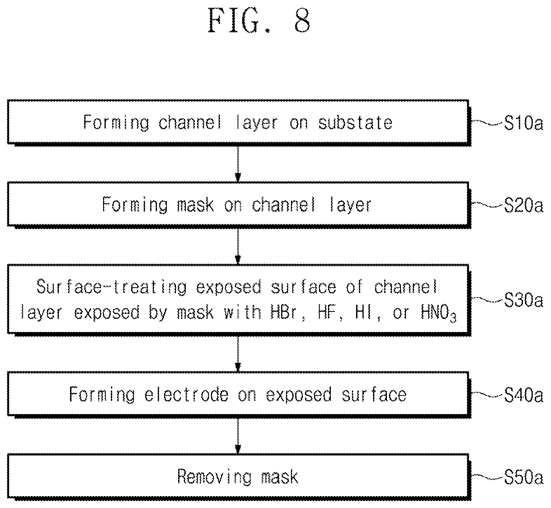

FIG. 8 is a flowchart of a method of manufacturing a semiconductor device according to some example embodiments.

Similar to the method of manufacturing the semiconductor device of FIG. 2, according to an example embodiment, a semiconductor device may be manufactured according to FIG. 8.

Referring to FIG. 8, a channel layer may be formed on a substrate in S10a. A mask layer may be formed on the channel layer in S20a. Thereafter, an exposed surface of the channel layer exposed by the mask may be surface-treated using one of HBr, HF, HI, or HNO₃ in S30a. Afterwards, an electrode may be formed on the exposed surface in S40a. Then, the mask may be removed in S50a to obtain the semiconductor device including the substrate, the channel layer, and the electrode.

A method of manufacturing the semiconductor device according to example embodiments may reduce the contact resistance between the two-dimensional (2D) material and the electrode through the surface treatment.

While example embodiments are described above, it will be apparent to those skilled in the art that many modifications and variations can be made without departing from the spirit and scope of the following claims. Accordingly, the example embodiments should be considered in all respects as illustrative and not restrictive, with the spirit and scope as defined by the appended claims.

What is claimed is:

1. A method of manufacturing a semiconductor device, the method comprising:
forming a channel layer on a substrate;
forming a mask on the channel layer;
surface-treating an exposed surface of the channel layer exposed from the mask;
forming an electrode on the exposed surface; and
removing the mask,
wherein the channel layer comprises a two-dimensional material, and
wherein the surface-treating comprises surface-treating the exposed surface with hydrogen chloride (HCl).

2. The method of claim 1, wherein the surface-treating further comprises removing an oxide group from the exposed surface.

3. The method of claim 1, wherein the surface-treating further comprises removing impurities from the exposed surface.

4. The method of claim 1, wherein the surface-treating further comprises surface-treating the exposed surface with HCl in a liquid state, and
wherein a concentration of HCl in the liquid state is 1% or more and 10% or less.

5. The method of claim 1, wherein the electrode comprises at least one of Cr, Pd, Au, Ti, Pt, Bi, Ag, Co, Ni, Cu, Sb, Sn, Al, or graphene.

6. The method of claim 1, wherein the two-dimensional material comprises one of Si, Ge, MoS₂, WS₂, MoSe₂, ReS₂, WSe₂, or graphene.

7. The method of claim 1, wherein the two-dimensional material comprises WSe₂,
wherein the electrode comprises Cr, and
wherein the channel layer is configured as an N-type channel.

8. The method of claim 1, wherein the two-dimensional material comprises WSe₂,
wherein the electrode comprises Pd, and
wherein the channel layer is configured as a P-type channel.

9. The method of claim 1, wherein the forming the mask comprises one of performing a photolithography process or performing an electron beam lithography process.

10. The method of claim 1, wherein the substrate comprises one of SiO₂, Al₂O₃, HfO₂, and h-BN.

11. A method of manufacturing a semiconductor device, the method comprising:
forming a channel layer on a substrate;
forming a mask on the channel layer;
surface-treating an exposed surface of the channel layer exposed from the mask;
forming an electrode on the exposed surface; and
removing the mask,
wherein the channel layer includes a two-dimensional material, and
wherein the surface-treating comprises surface-treating the exposed surface with one of HBr, HF, HI, or HNO₃.

12. The method of claim 11, wherein the surface-treating further comprises surface-treating the exposed surface with one of HBr, HF, HI, or HNO₃ in a liquid state.

13. The method of claim 11, wherein the surface-treating further comprises removing an oxide group from the exposed surface of the channel layer.

14. The method of claim 11, wherein the surface-treating further comprises removing impurities from the exposed surface.

15. The method of claim 11, wherein the two-dimensional material comprises WSe₂,
wherein the electrode comprises Cr, and
wherein the channel layer is configured as an N-type channel.

16. The method of claim 11, wherein the two-dimensional material comprises one of Si, Ge, MoS₂, WS₂, MoSe₂, ReS₂, WSe₂, or graphene.

17. The method of claim 11, wherein the two-dimensional material comprises WSe₂,
wherein the electrode comprises Pd, and
wherein the channel layer is configured as a P-type channel.

18. The method of claim 11, wherein the electrode comprises at least one of Cr, Pd, Au, Ti, Pt, Bi, Ag, Co, Ni, Cu, Sb, Sn, Al, or graphene.

19. The method of claim 11, wherein the substrate includes one of SiO₂, Al₂O₃, HfO₂, or h-BN.

20. A method of manufacturing a semiconductor device, the method comprising:
forming a channel layer on a substrate;
forming a mask on the channel layer;
surface-treating an exposed surface of the channel layer exposed from the mask;
forming an electrode on the exposed surface; and
removing the mask,
wherein the channel layer includes a two-dimensional material, and
wherein the surface-treating comprises surface-treating the exposed surface with HCl at a concentration of 5%.
